(19) United States
(12) Patent Application Publication
(10) Pub. No.: US 2010/0012481 A1
(43) Pub. Date: Jan. 21, 2010

(54) DEPOSITION SYSTEM HAVING IMPROVED MATERIAL UTILIZATION

(76) Inventors: G. X. Guo, Palo Alto, CA (US); K. A. Wang, Cupertino, CA (US)

Correspondence Address: XIN WEN, 3449 RAMBOW DRIVE, PALO ALTO, CA, 94306, US

(21) Appl. No.: 12/176,411

(22) Filed: Jul. 21, 2008

(51) Int. Cl. C23C 14/35

(52) U.S. Cl. 204/192.12; 204/298.2

(57) ABSTRACT

A substrate processing system includes a processing chamber that can house a substrate therein; a target comprises a sputtering surface in the processing chamber, wherein the substrate is configured to receive material sputtered off the sputtering surface; a magnetron positioned adjacent to the target, wherein the magnetron can produce two erosion grooves separated by a distance S on the sputtering surface, wherein at least one of the two erosion grooves is characterized by an erosion width W; and a first transport mechanism that can move the magnetron in N steps along a travel path in a first direction. N is an integer. The magnetron can stop at each of the N steps to allow materials to be sputtered off the sputtering surface and to be deposited on the substrate. The N steps have substantially the same step size. The step size is approximately equal to the erosion width W.

### TECHNICAL FIELD

This application relates to an apparatus for depositing material on a substrate.

### BACKGROUND

Material deposition is widely used in window glass coating, flat panel display manufacturing, coating on flexible films (such as webs), hard disk coating, industrial surface coating, semiconductor wafer processing, photovoltaic panels, and other applications. Materials are sputtered or vaporized from a target source and deposited on a substrate. Conventional deposition systems have various drawbacks in material utilization. For example, referring to FIGS. 1A-1E, a deposition system 100 includes a rectangular target 110 above a substrate 115 in a vacuum chamber 120. A stationary magnetron 130 is held above the target 110. The substrate 115 can be transported in a direction 150 relative to the target 110 and the magnetron 130 to allow uniform deposition on the top surface of the substrate 115. A power supply 140 can produce an electric bias between the target 110 and walls of the vacuum chamber 120.

The magnetron 130 (FIG. 1C) includes a magnetic pole 132 of a first polarity and a magnetic pole 135 of a second polarity opposite to the first polarity. The magnetron 130 can produce magnetic flux outside of the sputtering surface 112 on the lower side of the target 110 (as shown in FIG. 1B) to confine plasma gas near the sputtering surface 112. More electrons can be confined near locations where the magnetic field parallel to the sputtering surface 112 and where the magnetic field is the strongest. A close loop can be formed to trap the electrons by locations having local-maximum magnetic field strength. The close path can guide the migration path for the trapped electrons near the sputtering surface 112. The closed-loop magnetic field can enhance the ionization efficiency of the sputtering gas (i.e. the plasma) to more effectively confine electrons near the sputtering surface 112. The enhanced ionization can allow lower operating pressure during sputter deposition, which is easier to implement in operation.

A drawback of the deposition system 100 is that it has low target material utilization. After a period of sputtering operations, as shown in FIGS. 1D and 1E, a non-uniform erosion pattern 115 usually appears on the sputtering surface 112 after a period of sputtering operations. The erosion pattern 115 typically includes a close-looped groove that matches the magnetic field strength of the magnetron 130. The most erosion occurs at target locations 116 that correspond to locations having high magnetic field strength where the sputtering gas is enhanced the most. The target 110 has to be replaced before the target locations 116 reach the top surface of the target 110. The target 110 is discarded and the unused target material 117 is wasted.

There is therefore a need to increase the utilization of target materials and to minimize waste in material depositions.

### SUMMARY

In one aspect, the present invention relates to a substrate processing system including a processing chamber that can house a substrate therein; a target comprises a sputtering surface in the processing chamber, wherein the substrate can receive material sputtered off the sputtering surface; a magnetron positioned adjacent to the target, wherein the magnetron can produce two erosion grooves separated by a distance S on the sputtering surface, wherein at least one of the two erosion grooves is characterized by an erosion width W; and a first transport mechanism that can move the magnetron in N steps along a travel path in a first direction, wherein N is an integer, wherein the magnetron can stop at each of the N steps to allow materials to be sputtered off the sputtering surface and to be deposited on the substrate, wherein the N steps have substantially the same step size, wherein the step size is approximately equal to the erosion width W.

In another aspect, the present invention relates to a substrate processing system including a processing chamber that can house a substrate therein; and a plurality of deposition sources, each comprising a target comprises a sputtering surface in the processing chamber, wherein the substrate can receive material sputtered off the sputtering surface; a magnetron positioned adjacent to the target, wherein the magnetron can produce two erosion grooves separated by a distance S on the sputtering surface, wherein at least one of the two erosion grooves is characterized by an erosion width W; and a first transport mechanism that can move the magnetron in N steps along a travel path in a first direction, wherein N is an integer, wherein the magnetron can stop at each of the N steps to allow materials to be sputtered off the sputtering surface and to be deposited on the substrate, wherein the N steps have substantially the same step size, wherein the step size is approximately equal to the erosion width W. The substrate processing system also includes a second transport mechanism that can move the substrate relative to the targets in the plurality of deposition sources.

In another aspect, the present invention relates to a method for substrate processing. The method includes placing a substrate a processing chamber; mounting a sputtering surface of a target in the processing chamber, placing a magnetron adjacent to the target; sputtering material off the sputtering surface to deposit on the substrate; producing two erosion grooves separated by a distance S on the sputtering surface, wherein one of the two erosion grooves is characterized by an erosion width W; moving the magnetron along a travel path in a first direction by a step size approximately equal to the erosion width W; and after the step of moving the magnetron, sputtering additional material off the sputtering surface to deposit on the substrate.

Implementations of the system may include one or more of the following. The ratio S/W can in a range of about N−0.1 and N+0.1. The step size is in a range of about 0.9 W and about 11 W. Both the two erosion grooves can be characterized by the erosion width W. The erosion width W can be defined by a distance between half-full-depths in the one of the two erosion grooves. Each of the two erosion grooves can include at least a segment substantially perpendicular to the first direction. The magnetron can produce a close-loop erosion pattern in the sputtering surface after a period of material deposition, wherein the close-loop erosion pattern comprises two substantially parallel erosion grooves separated by the distance S. The two substantially parallel erosion grooves are aligned substantially perpendicular to the first direction. The substrate processing system can further include a second transport mechanism that can move the substrate relative to the target. The sputtering surface can be positioned to face the substrate in the processing chamber. The magnetron can be positioned adjacent to a back surface of the target opposite to the sputtering surface. The substrate processing system can further include a power supply that can produce a bias voltage between the target and the processing chamber. The substrate processing system can further include a shunting device that can reduce the amount of deposition when the magnetron is positioned at a step at the end of the travel path. The first transport mechanism can move the magnetron along a travel path after the N steps by approximately MS, wherein M is an integer.

Embodiments may include one or more of the following advantages. Embodiments may include one or more of the following advantages. The described deposition systems and methods can improve the usage efficiency of target material and can therefore reduce target cost and reduce work for the target replacement. The described target arrangements and methods are applicable to different target and magnetron configurations.

The details of one or more embodiments are set forth in the accompanying drawings and in the description below. Other features, objects, and advantages of the invention will become apparent from the description and drawings, and from the claims.

### BRIEF DESCRIPTION OF THE DRAWINGS

FIG. 1A is a perspective view of a conventional deposition system.

FIG. 1B is a cross-sectional view of the conventional deposition system of FIG. 1A.

FIG. 1C is a bottom perspective view of the magnetron in the conventional deposition system of FIG. 1A.

FIG. 1D is a perspective view of the target in the conventional deposition system of FIG. 1A showing an erosion pattern on the target's sputtering surface.

FIG. 1E is a cross-sectional view of the target along line A-A FIG. 1D showing an erosion pattern.

FIG. 2A is a cross-sectional view of a deposition system in accordance with the present invention.

FIG. 2B is a bottom perspective view of the magnetron in the deposition system of FIG. 2A.

FIG. 2C is a perspective view of the deposition system in FIG. 2A.

FIG. 2D is a cross-sectional perspective view of the deposition system of FIG. 2A.

FIG. 3A is a cross-sectional view of an arrangement of a moveable magnetron and a target in the deposition system of FIG. 2A when the magnetron is at a first position.

FIG. 3B is a cross-sectional view of the moveable magnetron and the target in the arrangement shown in FIG. 3A when the magnetron is at a second position.

FIG. 3C is a perspective view showing an erosion pattern on the target after a period of deposition in the configuration shown in FIGS. 3A and 3B.

FIGS. 4A-4C are cross-sectional views of an improved arrangement of a moveable magnetron and a target in the deposition system of FIG. 2A when the moveable magnetron is at different positions.

FIG. 4D is a cross-sectional view showing the erosion pattern on the target after a period of deposition in the configuration shown in FIGS. 4A-4C.

FIG. 4E is a cross-sectional view of another improved arrangement of a moveable magnetron and a target in the deposition system of FIG. 2A.

FIG. 5 illustrates the relationships among the dimensions of the magnetron and target, and the step width of the moveable magnetron.

FIG. 6 is a cross-sectional view of another improved deposition system comprising two deposition sources in a deposition chamber.

FIG. 7A is a cross-sectional view of another improved deposition system comprising two deposition chambers each comprising two deposition sources each including a moveable magnetron or a stepping magnetron.

FIG. 7B is a cross-sectional perspective view of the deposition system of FIG. 6A.

FIG. 7C is a perspective view of the deposition system of FIG. 6A.

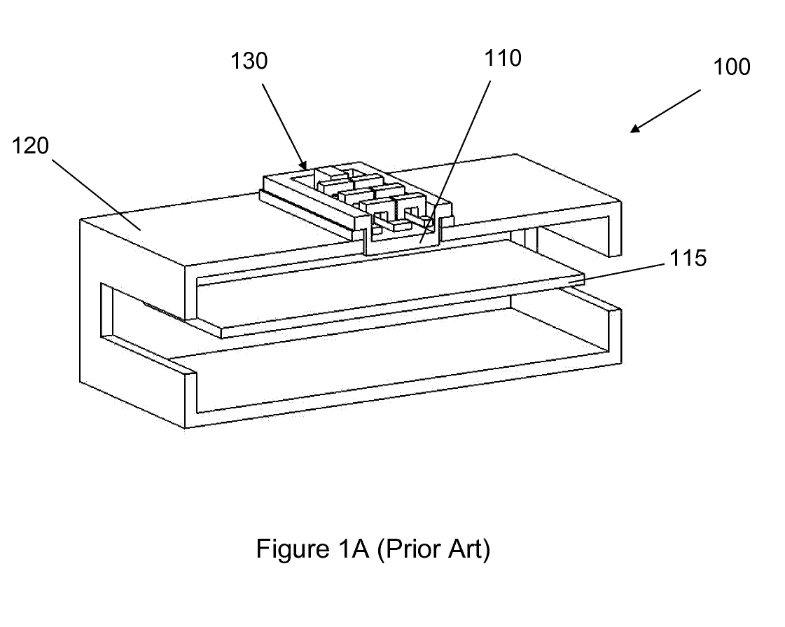

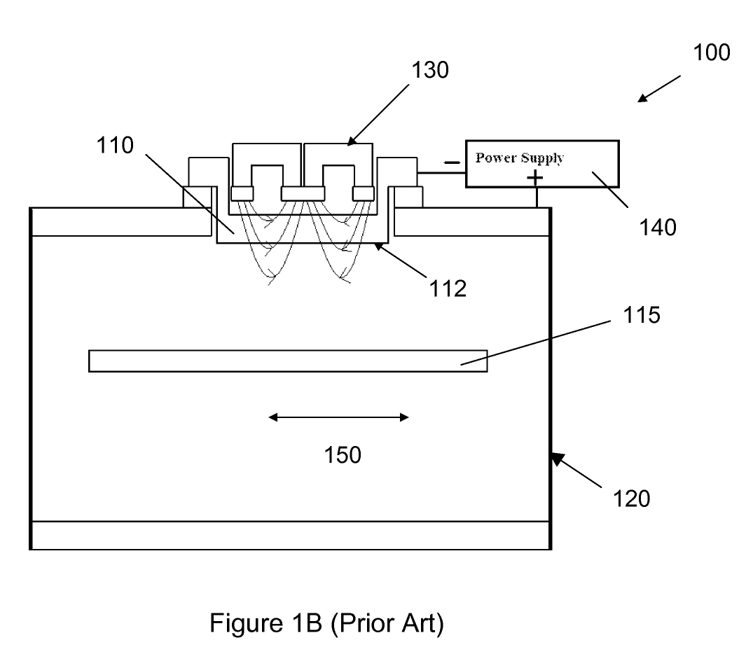

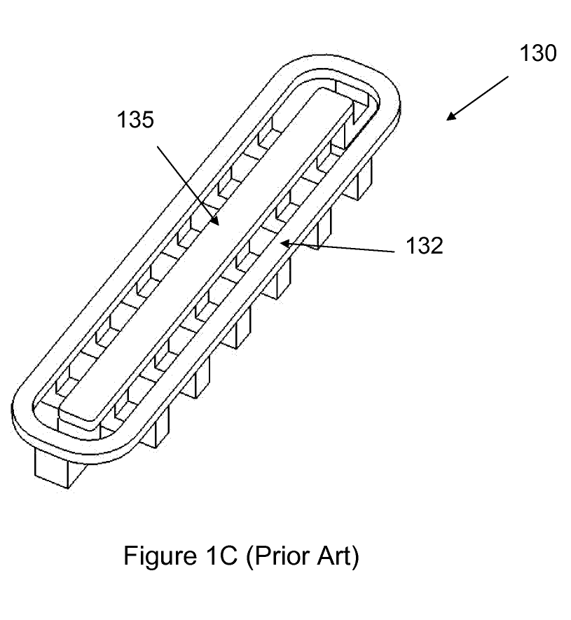

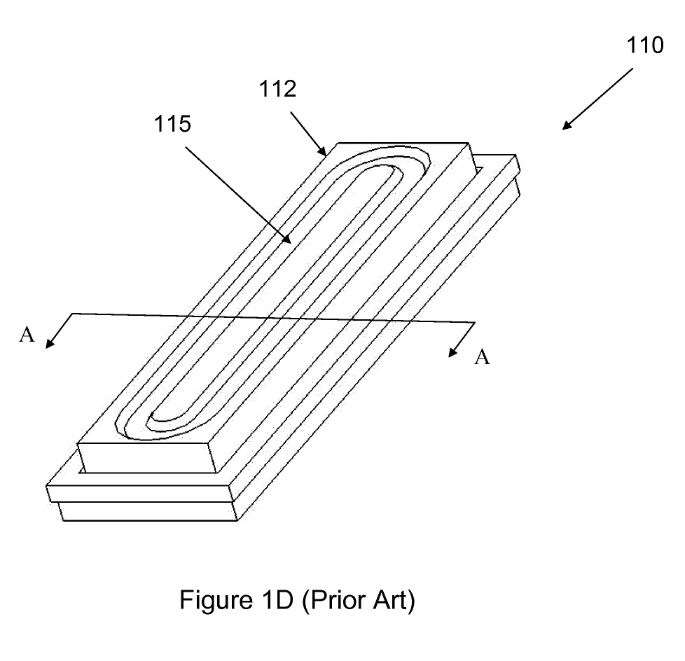

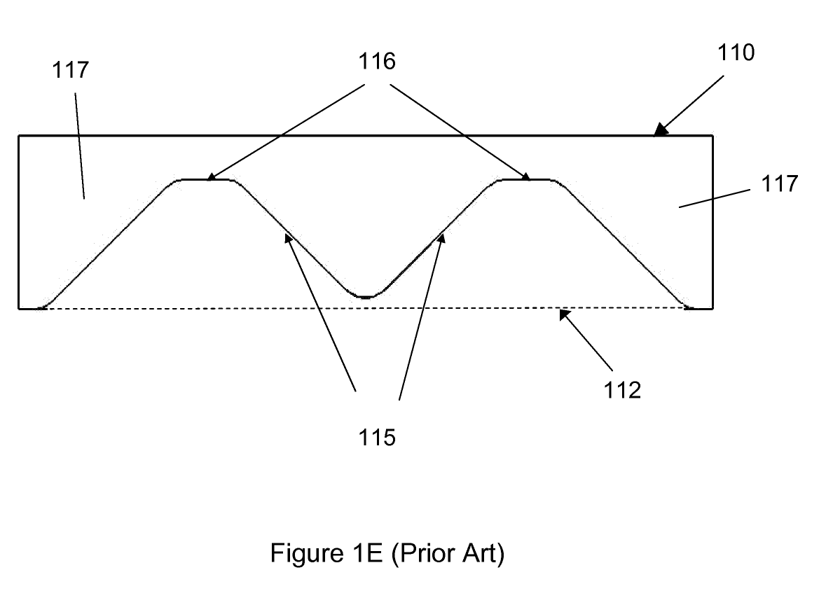

### DETAILED DESCRIPTION

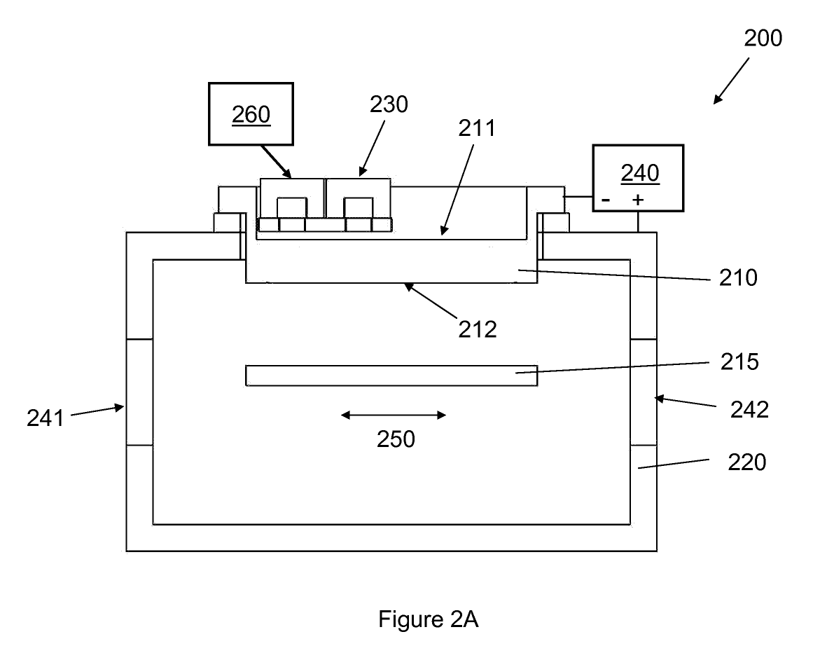

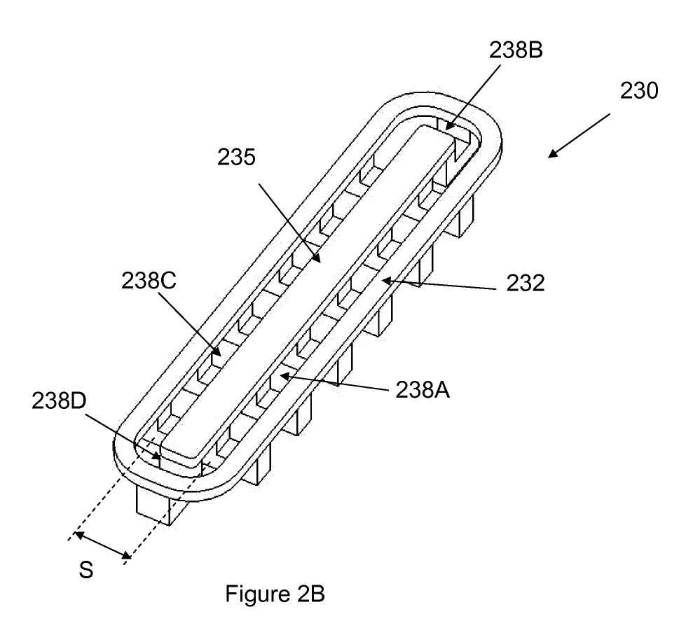

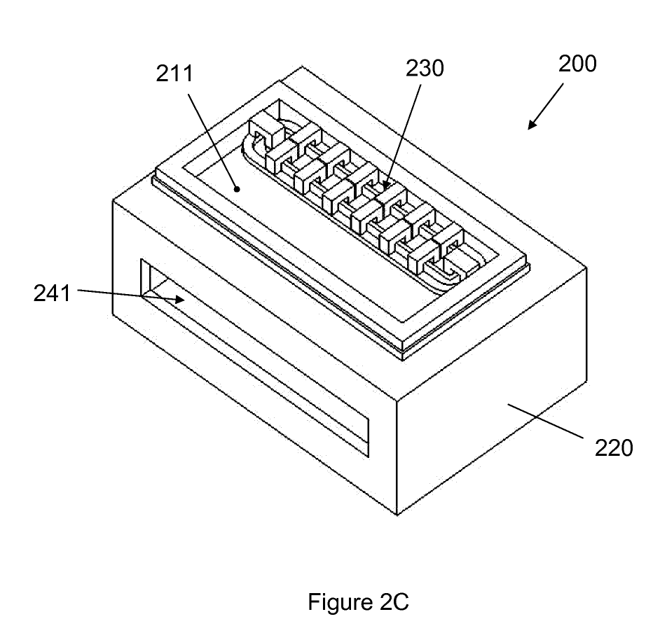

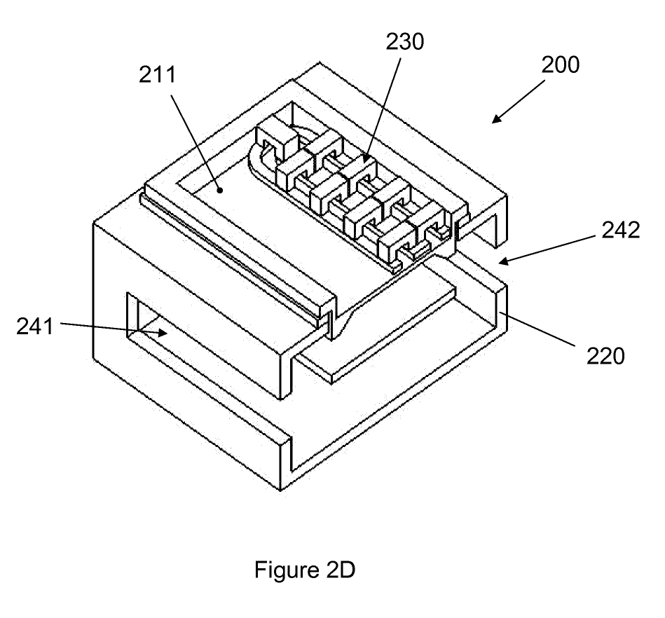

Referring to FIGS. 2A-2C, a deposition system 200 includes in a processing chamber 220 having openings 241 and 242. Doors (not shown) can seal the openings 241 and 242 to keep the processing chamber 220 in a vacuum environment. A substrate 215 can be moved by a transport mechanism in a direction 250. The substrate 215 can be moved into and out of the processing chamber 220 through the openings 241 and 242. A target 210 is positioned above the substrate 215. The target 210 includes a back surface 211 and a sputtering surface 212 facing the substrate 215. The sputtering surface 212 is positioned in the processing chamber 220. The processing chamber 220 is exhausted to a vacuum environment for deposition. During deposition, target material is sputtered off the sputtering surface 212 in a vacuum environment and is deposited on the substrate 215.

A moveable magnetron 230 is positioned adjacent to the back surface 211 of the target 210. The magnetron 230 can be moved across the back surface 211 by a transport mechanism 260. The relative movement between to the target 210 and the substrate 215 allows uniform deposition of the target material on the substrate 215. A power supply 240 can produce an electric bias between the target 210 and walls of the processing chamber 220. The electric bias can be in the form of DC, AC, or RF voltages and can induce plasma gas in the processing chamber 220. The ions in the plasma are attracted to the target 210 and can sputter off target material from the sputtering surface 212. The magnetron 230 can increase ionization efficiency of the plasma by trapping excited electrons near the sputtering surface 212 by Lorentz force. The magnetron 230 can beneficially reduce deposition pressure and allows lower electric bias voltage between the target 210 and the walls of the processing chamber 220. Details about deposition systems are also disclosed in the commonly assigned pending U.S. patent application Ser. No. 11/847,956 (ASC009), tilted “Substrate processing system having improved substrate transport”, filed Aug. 30, 2007, the content of which is incorporated herein by reference.

Referring to FIG. 2B, the magnetron 230 includes magnetic poles 232 and 235 of opposite polarities and separated by gaps 238A-238D which form a close loop between the magnetic poles 232 and 235. The two long gaps 238A and 238C are separated by a distance “S”. The magnetron 230 can produce magnetic flux between the magnetic poles 232 and 235. The magnetic flux lines near the sputtering surface 212 to confine the plasma gas near the sputtering surface 212. The magnetic field confinement of electrons is the strongest when the magnetic field is parallel to the sputtering surface 212. More electrons thus tend to be confined at locations wherein the magnetic field is parallel to the sputtering surface 212. The locations of local-maximum magnetic field strength by the magnetron 230 can form a close loop adjacent to the gaps 238A-238D, which traps the most electrons in the plasma gas. The close loop can guide the movement of the trapped electrons and extend their stay near the sputtering surface 212. The closed-loop magnetic field can enhance ionization efficiency of the plasma to more effectively confine electrons near the sputtering surface 212.

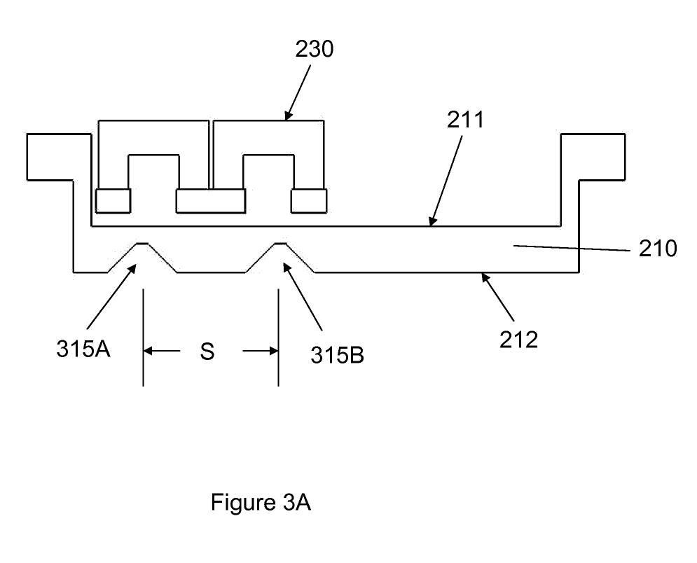

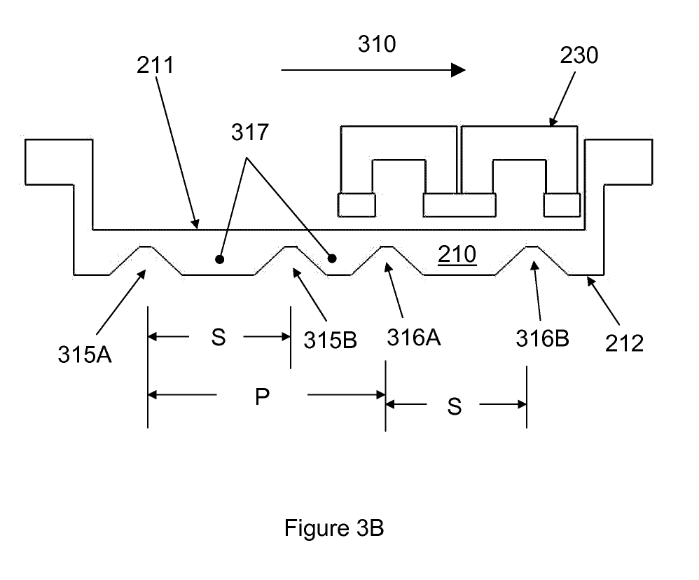

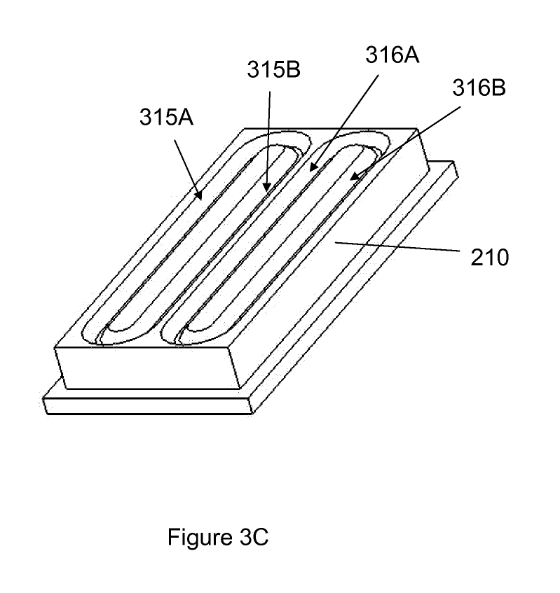

The magnetron 230 needs to be properly designed to increase target material usage and to reduce material waste. An example of undesirable target usage is shown in FIGS. 3A-3C (components other than the target and the magnetron are not shown for clarity reason). The magnetron 230 is shown to be positioned at the left end of the target 210 in FIG. 3A. Erosion grooves 315A and 315B appear in the sputtering surface 212 after a period of sputtering deposition. The distance between the erosion grooves 315A and 315B is “S”, the same distance between the gaps 238A and 238C between the magnetic poles 232 and 235 in the magnetron 230. The magnetron 230 can be moved by the transport mechanism 260 (shown in FIG. 2A) along a direction 310 to the right end of the target 210 (FIG. 3B). In some configuration, the direction 310 is substantially perpendicular to the direction of the erosion grooves 315A, 315B, 316A, and 316B. If the displacement “P” of the magnetron 230 is bigger than “S”, another set of erosion grooves 316A and 316B appear in the sputtering surface 212 after a period of deposition with the magnetron 230 at this second position (as shown in FIGS. 3B and 3C). The erosion grooves 316A and 316B are also separated by a distance “S”. The target 210 needs to be replaced before the troughs of the grooves 315A-316B reach the back surface 211 of the target 210. Unused target portions 317 will be discarded, which results in low target utilization typically below 30%.

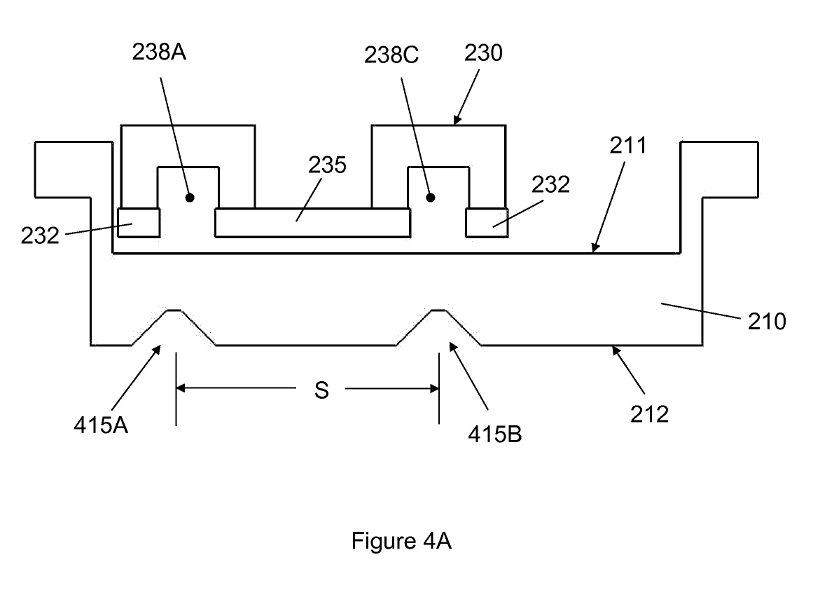

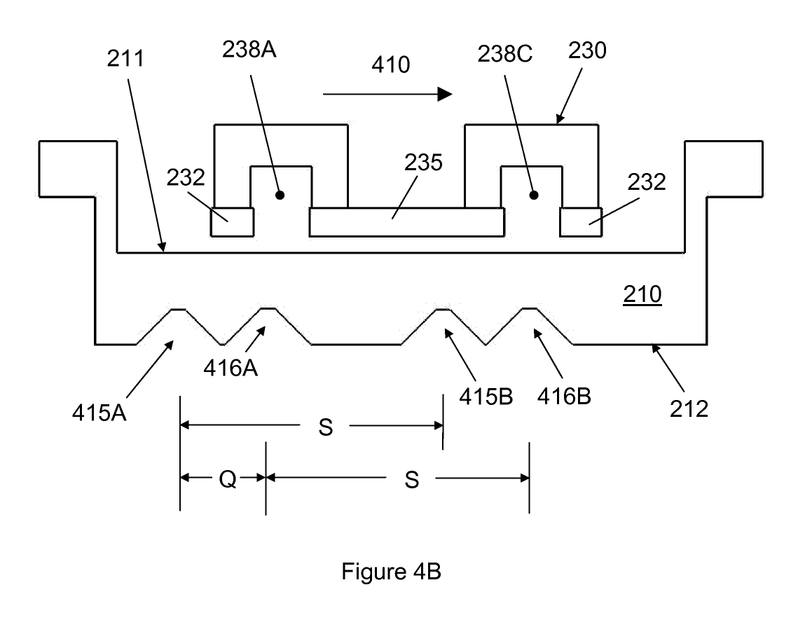

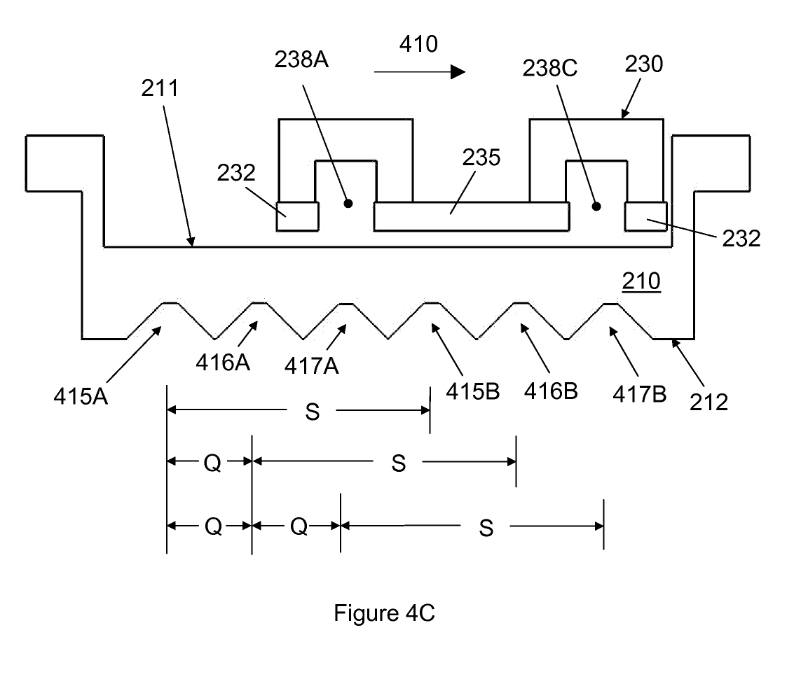

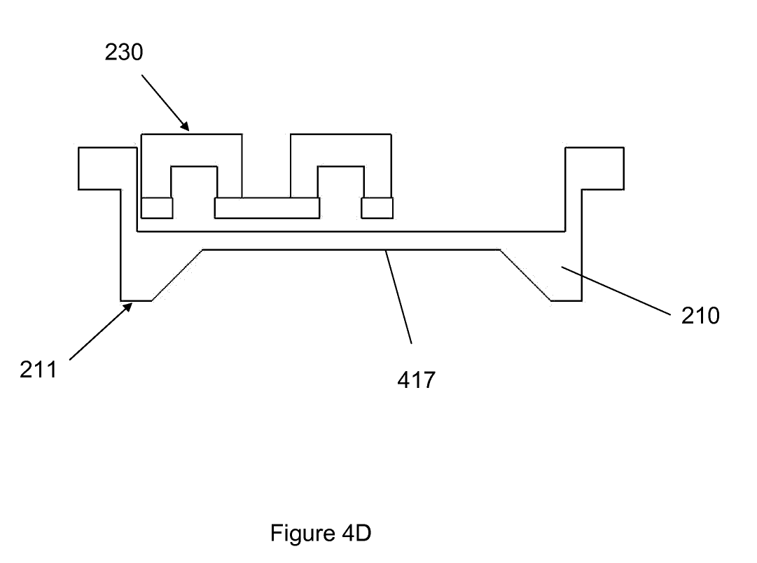

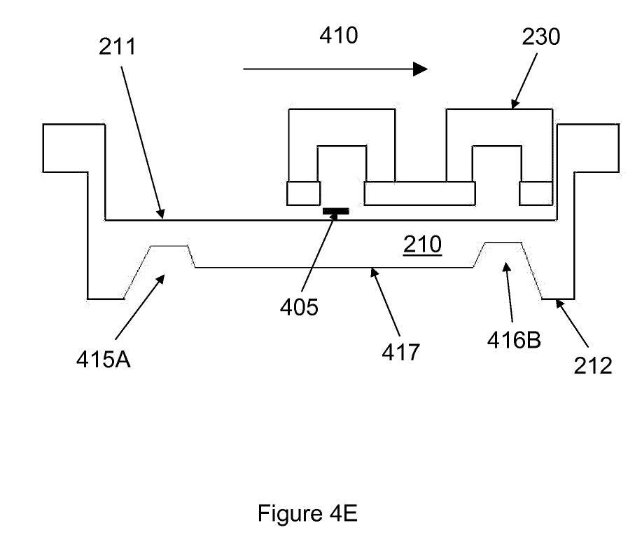

The dimensions of the magnetron 230 and the target 210 as well as the operation of the magnetron 230 can be designed to maximize target material usage and to reduce material waste. Referring to FIGS. 4A-4C (components other than the target and the magnetron are not shown for viewing clarity), the magnetron 230 is first positioned at the left end of the target 210 in FIG. 4A to produce erosion grooves 415A and 415B after a period of sputtering deposition. The distance between the erosion grooves 415A and 415B is “S”, the distance between the gaps 238A and 238C between the magnetic poles 232 and 235 in the magnetron 230. The magnetron 230 is moved by the transport mechanism 260 (shown in FIG. 2A) along a direction 410 by a step (FIG. 4B). The step size “Q” is smaller than “S”. Sputtering and deposition at this step produces another set of erosion grooves 416A and 416B. The direction 410 can be substantially perpendicular to the erosion grooves 415A and 415B (and erosion grooves 416A-417B as discussed below).

The magnetron 230 is moved along a direction 410 by another step with the same step size “Q” (FIG. 4C). Sputtering and deposition at this step produces another set of erosion grooves 417A and 417B. The magnetron 230 is moved (shown in FIGS. 4A-4C) from the left end to the right end of the target 210 in two steps. It should be noted that FIGS. 4A-4C are intended to illustrate an example of the invention concept. A magnetron can move from one end to the other end of the target in one or more steps. The erosion grooves 415A and 415B, 416A and 416B, 417A and 417B are staggered with each other and even distributed across the sputtering surface 212. The movement and deposition steps shown in FIGS. 4A-4C can be repeated in smaller steps so that the erosion groves overlap and can form a smooth surface. As a result, as shown in FIG. 4D, a smoother eroded surface 417 is formed on the sputtering surface 212 after the magnetron 230 moves back and forth the back of the target 210 multiple times. The deposition events can occur at each step when the magnetron travels along and reverse to the direction 410. A large number of steps can result in smoother eroded surface 417 and more even erosion in the target 210. Using such approach, more than 70% of target material can be used before a target needs to be replaced.

It is found that the erosion grooves (e.g. 415A and 417B) at the ends of the travel path are somewhat deeper, which is caused by the slower magnetron movement at the reverse motion at the ends of the travel path or intentional slowing down the magnetron speed at end of the travel to improve deposition uniformity by increasing the erosion near edge of the target. The slowing down of the magnetron also causes excess overlap of erosion groves near center of the target and reduces target utilization. In addition, the excess erosion near target center degrades deposition uniformity. It is therefore desirable to reduce the amount of deposition and erosion on the target surface caused by the slower magnetron movement at the two end positions of the target. In some embodiments, referring to FIG. 4E, a shunting device 405 is placed near the back surface 211 adjacent to the magnetic poles 232 and 235 when the magnetron 230 is positioned at the end of the travel path. The shunting devices 405 can be made of a permanent magnetic material such as 400 series stainless steel. The shunting devices 405 can interrupt and reduce the magnetic flux lines the magnetic poles 232 and 235 and thus reduce the plasma ionization efficiency and thus decrease the amount of deposition. The amount of erosion can thus be reduced at the end steps. The shunt can be placed at any location where excessive erosion is occurring.

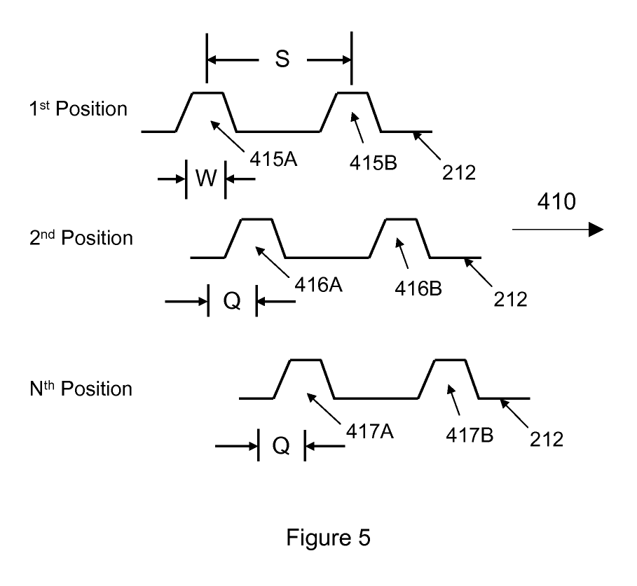

FIG. 5 illustrates the geometric relationships among the magnetron, the target, and the movement of the moveable magnetron. FIG. 5 depicts the erosion patterns on the sputtering surfaces 212 shown in FIGS. 4A-4C. Each erosion groove 415A-417B is characterized by a width “W”. W can be the distance between the half full depths of the erosion grove. As described above, the distance between the erosion grooves at each fixed deposition position is “S”. The step size for the magnetron's movement is “Q”, which is substantially the same for the N steps. In accordance to the present invention, the smoothness of the sputtering surface 212 can be optimized with the following relationships:

Q≈W Eqn. (1)

that is, the step size “Q” is selected to be approximately the characteristic “W”, or within +/−10% of “W”, that is, in a range of about 0.9 W and about 1.1 W.

Equation (1) assures the adjacent erosion grooves 415A-417B to be densely packed on the sputtering surface 212.

In addition, it is desirable to have

S=NQ≈NW Eqn. (2)

wherein N is an integer number of steps and N≧2. For example, N can be 10. Equation (2) assures the erosion grooves 415A-417B to be evenly distributed across the sputtering surface 212.

Equation (2) shows that the separation between the long gaps 238A and 238C in the magnetron is desirably approximately an integer multiple of the characteristic width “W” in an erosion groove. Alternatively, S/W is within 0.1 of the integer N. Moreover, the magnetron is desirably moved by the integer multiple (i.e. S.W) steps to achieve even erosion and reduce target material waste.

Also from Equations (1) and (2), the travel distance “T” for the magnetron is

T=(N−1)W Eqn. (3)

The travel distance “T” is related to the clear distance that the magnetron 230 can move on the back surface of the target 210. Equation (3) thus sets forth a constraint between the dimensions of the target and the magnetron, and the selection of the step size for the magnetron.

In general, the travel distance can be longer than the example shown in FIG. 5. After a magnetron is moved to the Nth position in the first segment of travel, the magnetron can move additional (N+1) steps into a second segment of travel. The movement from first to second segment of the travel can be substantially faster than the movement within each segment or the sputtering power is off during the movement between segments to maintain uniform erosion across target. The movement pattern from the 2^{nd} to the Nth steps are repeated as shown in FIG. 5 in the second segment of travel. The magnetron and the target can be designed to have any integer number of segments of travel. We thus have

T=(N−1)W+MS Eqn. (4)

wherein “M” is an integer.

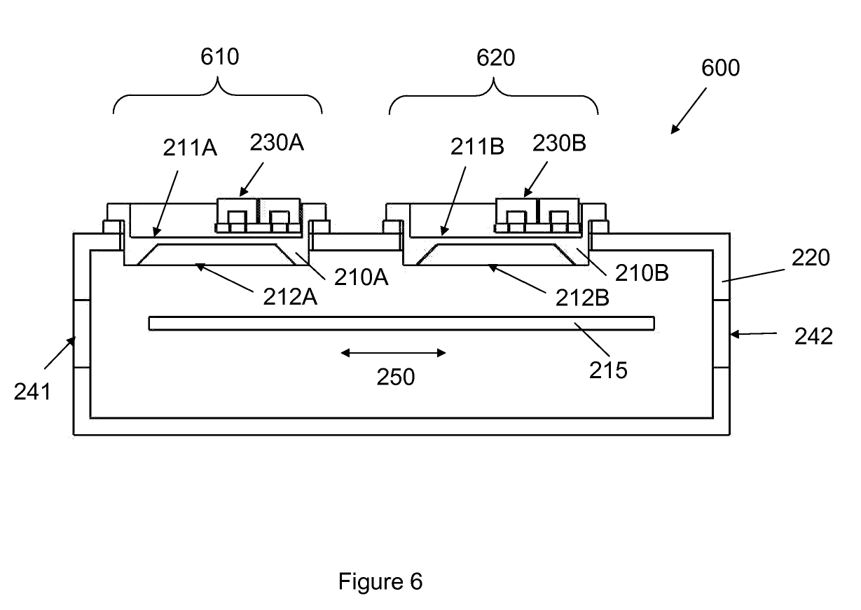

The described systems and methods are compatible with other configurations. Referring to FIG. 6, a deposition system includes a processing chamber 220 and two deposition sources 610 and 620 that respectively include a magnetron 230A or 230B, and a target 210A or 210B. The targets 210A and 210B respectively include sputtering surfaces 212A and 212B, and back surfaces 211A and 211B. The usage of the targets 210A and 210B can be maximized using the approaches as described above.

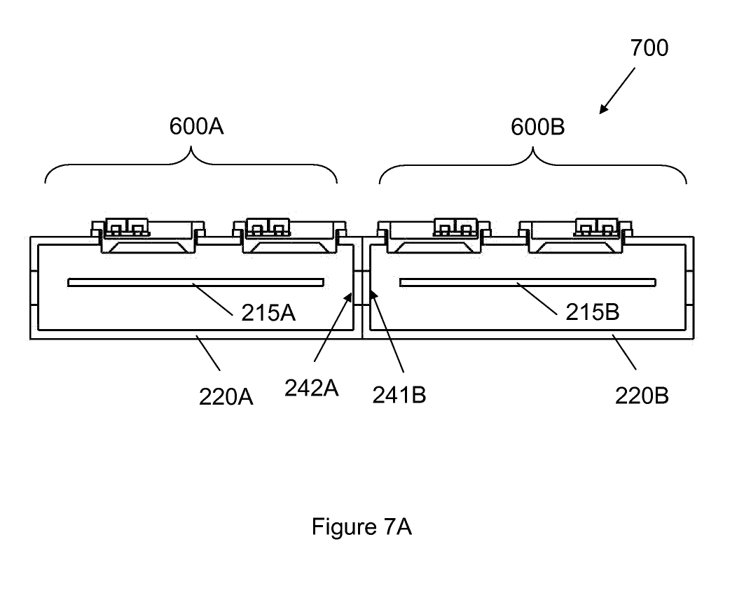

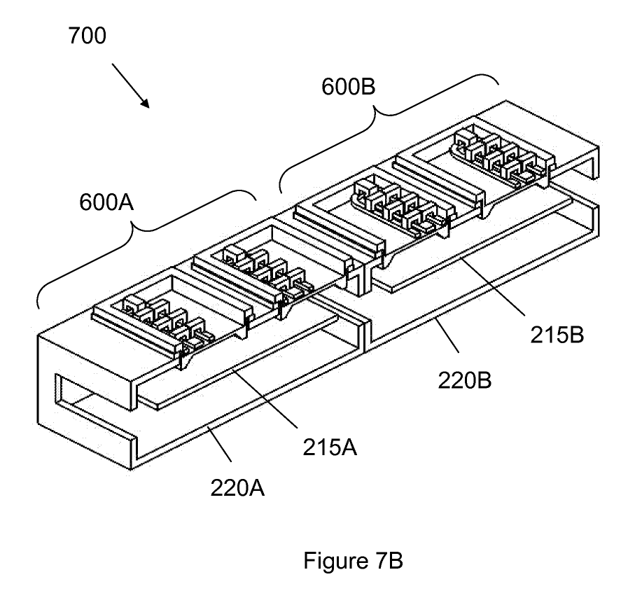

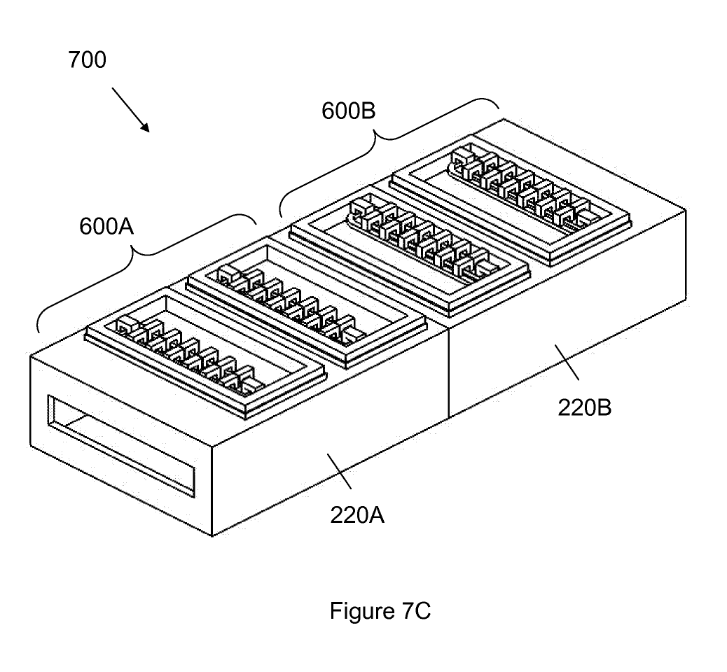

In some embodiments, referring to FIGS. 7A-7C, a deposition system 700 includes two interconnected deposition systems 600A and 600B respectively including processing chambers 220A and 220B. The processing chamber 220A includes an opening 242A that is registered to an opening 241B in the processing chamber 220B. A gate can be opened of closed to allow a substrate 215A or 215B to move between the processing chambers 220A and 220B.

It is understood that the disclosed systems and methods are compatible with other configurations without deviating from the spirit of the present invention. The disclosed processing chamber is compatible with many different types of processing operations such as physical vapor deposition (PVD), thermal evaporation, thermal sublimation, sputtering, chemical vapor deposition (CVD), plasma enhanced chemical vapor deposition (PECVD), ion etching, or sputter etching. The targets, the magnetrons, and the substrate can be positioned in relative positions other than the examples described above. The transport mechanisms for the magnetron and the substrate can take many different forms.

Examples of target materials compatible with the described systems and methods include aluminum (Al), aluminum zinc (AlZn), aluminum zinc oxide (AlZnO), aluminum oxide (Al2O3), aluminum nitride (AlN), aluminum copper (AlCu), aluminum silicon (AlSi), aluminum silicon copper (AlCuSi), aluminum fluoride (AlF), antimony (Sb), antimony telluride (SbTe), barium (Ba), barium titanate (BaTiO), barium fluoride (BaF), barium oxide (BaO), barium strontium titanate (BaSrTiO), barium calcium cuprate (BaCaCuO), bismuth (Bi), bismuth oxide (BiO), bismuth selenide (BiSe), bismuth telluride (BiTe), bismuth titanate (BiTiO), boron (B), boron nitride (BN), boron carbide (BC), cadmium (Cd), cadmium chloride (CdCl), cadmium selenide (CdSe), cadmium sulfide (CdS), CdSO, cadmium telluride (CdTe), CdTeHg, CdTeMn, cadmium stannate (CdSnO), carbon (C), cerium (Ce), cerium fluoride (CeF), cerium oxide (CeO), chromium (Cr), chromium oxide (CrO), chromium silicide (CrSi), cobalt (Co), copper (Cu), copper oxide (CuO), copper gallium (CuGa), CuIn, CuInSe, CuInS, CuInGa, CuInGaSe (CIGS), CuInGaS, Dy, Er, ErBaCuO, Eu, Gd, Ge, GeSi, Au, Hf, HfC, HfN, Ho, In, InO, InSnO (ITO), Ir, Fe, FeO, La, LaAlO, LaNiO, LaB, LaO, Pb, PbO, ObTe, PbTiO3, PbZrO, PbZrTiO (PZT), LiNbO, Mg, MgF, MgO, Mn, MnO, Mo, MoC, MoSi. MoO, MoSe, MoS, Nd, NdGaO, Ni, NiCr, NiFe, NiO, NiV, Nb, NbC, NbN, NbO, NeSe, NbSi, NbSn, Pd, NiFeMoMn (permalloy), Pt, Pr, PrCaMnO (PCMO), Re, Rh, Ru, Sm, SmO, Se, Si, SiO, SiN, SiC, SiGe, Ag, Sr, SrO, SrTiO (STO), Ta, TaO, TaN, TaC, TaSe, TaSi, Te, Tb, Tl, Tm, Sn, SnO, SnOF (SnO: F), Ti, TiB, TiC, TiO, TiSi, TiN, TiON, W, WC, WO, WSi, WS, W—Ti, V, VC, VO, Yb, YbO, Y, YbaCuO, YO, Zn, ZnO, ZnAlO (ZAO), ZnAl, ZnSn, ZnSnO, ZnSe, ZnS, ZnTe, Zr, ZrC, ZrN, ZrO, ZrYO (YSZ), and other solid element or compound.

What is claimed is:

1. A substrate processing system, comprising:
a processing chamber configured to house a substrate therein;
a target comprises a sputtering surface in the processing chamber, wherein the substrate is configured to receive material sputtered off the sputtering surface;
a magnetron positioned adjacent to the target, wherein the magnetron is configured to produce two erosion grooves separated by a distance S on the sputtering surface, wherein at least one of the two erosion grooves is characterized by an erosion width W; and
a first transport mechanism configured to move the magnetron in N steps along a travel path in a first direction, wherein N is an integer, wherein the magnetron is configured to stop at each of the N steps to allow materials to be sputtered off the sputtering surface and to be deposited on the substrate, wherein the N steps have substantially the same step size, wherein the step size is approximately equal to the erosion width W.

2. The substrate processing system of claim 1, wherein the ratio S/W is in a range of about N−0.1 and N+0.1.

3. The substrate processing system of claim 1, wherein the step size is in a range of about 0.9 W and about 1.1 W.

4. The substrate processing system of claim 1, wherein both the two erosion grooves are characterized by the erosion width W.

5. The substrate processing system of claim 1, wherein the erosion width W is defined by a distance between half-full-depths in the one of the two erosion grooves.

6. The substrate processing system of claim 1, wherein each of the two erosion grooves includes at least a segment substantially perpendicular to the first direction.

7. The substrate processing system of claim 1, wherein the magnetron is configured to produce a close-loop erosion pattern in the sputtering surface after a period of material deposition, wherein the close-loop erosion pattern comprises two substantially parallel erosion grooves separated by the distance S.

8. The substrate processing system of claim 7, wherein the two substantially parallel erosion grooves are aligned substantially perpendicular to the first direction.

9. The substrate processing system of claim 1, further comprising a second transport mechanism configured to move the substrate relative to the target.

10. The substrate processing system of claim 1, wherein the sputtering surface is positioned to face the substrate in the processing chamber.

11. The substrate processing system of claim 1, wherein the magnetron is positioned adjacent to a back surface of the target opposite to the sputtering surface.

12. The substrate processing system of claim 1, further comprising a power supply configured to produce a bias voltage between the target and the processing chamber.

13. The substrate processing system of claim 1, further comprising a shunting device configured to reduce the amount of deposition when the magnetron is positioned at a step at the end of the travel path.

14. The substrate processing system of claim 1, wherein the first transport mechanism is configured to move the magnetron along a travel path after the N steps by approximately equal MS, wherein M is an integer.

15. A substrate processing system, comprising:
a processing chamber configured to house a substrate therein;
a plurality of deposition sources, each comprising:
a target comprises a sputtering surface in the processing chamber, wherein the substrate is configured to receive material sputtered off the sputtering surface;
a magnetron positioned adjacent to the target, wherein the magnetron is configured to produce two erosion grooves separated by a distance S on the sputtering surface, wherein at least one of the two erosion grooves is characterized by an erosion width W; and
a first transport mechanism configured to move the magnetron in N steps along a travel path in a first direction, wherein N is an integer, wherein the magnetron is configured to stop at each of the N steps to allow materials to be sputtered off the sputtering surface and to be deposited on the substrate, wherein the N steps have substantially the same step size, wherein the step size is approximately equal to the erosion width W; and
a second transport mechanism configured to move the substrate relative to the targets in the plurality of deposition sources.

16. The substrate processing system of claim 15, wherein the ratio S/W is in a range of about N−0.1 and N+0.1.

17. The substrate processing system of claim 15, wherein the step size is in a range of about 0.9 W and about 1.1 W.

18. The substrate processing system of claim 15, wherein both the two erosion grooves are characterized by the erosion width W.

19. The substrate processing system of claim 15, wherein the erosion width W is defined by a distance between half-full-depths in the one of the two erosion grooves.

20. A method for substrate processing, comprising:
placing a substrate a processing chamber;
mounting a sputtering surface of a target in the processing chamber,
placing a magnetron adjacent to the target;
sputtering material off the sputtering surface to deposit on the substrate;
producing two erosion grooves separated by a distance S on the sputtering surface, wherein one of the two erosion grooves is characterized by an erosion width W;
moving the magnetron along a travel path in a first direction by a step size approximately equal to the erosion width W; and
after the step of moving the magnetron, sputtering additional material off the sputtering surface to deposit on the substrate.

21. The method of claim 20, further comprising:
moving the magnetron in N steps along the first direction, wherein the ratio S/W is in a range of about N−0.1 and N+0.1; and
after each of the N steps, sputtering additional material off the sputtering surface to deposit on the substrate.

22. The method of claim 20, wherein the step size is in a range of about 0.9 W and about 1.1 W.

23. The method of claim 20, wherein both the two erosion grooves are characterized by the erosion width W.

24. The method of claim 20, wherein the erosion width W is defined by a distance between half-full-depths in the one of the two erosion grooves.

25. The method of claim 20, further comprising producing a close-loop erosion pattern in the sputtering surface by the magnetron after a period of material deposition, wherein the close-loop erosion pattern comprises two substantially parallel erosion grooves separated by the distance S.

26. The method of claim 25, wherein the two substantially parallel erosion grooves are aligned substantially perpendicular to the first direction.

27. The method of claim 20, further comprising moving the substrate relative to the target.

28. The method of claim 20, further comprising positioning the sputtering surface of the target to face the substrate in the processing chamber.

29. The method of claim 20, further comprising positioning the magnetron adjacent to a back surface of the target opposite to the sputtering surface.

30. The method of claim 20, further comprising producing a bias voltage between the target and the processing chamber.

31. The method of claim 20, further comprising mounting a shunting device to reduce the amount of deposition when the magnetron is positioned at a step at the end of the travel path.

32. The method of claim 20, further comprising:
after the N steps, moving the magnetron by the first transport mechanism along the travel path by approximately equal MS, wherein M is an integer.
